(19) United States
(12) Patent Application Publication
(10) Pub. No.: US 2017/0168956 A1
(43) Pub. Date: Jun. 15, 2017

(54) BLOCK CACHE STAGING IN CONTENT DELIVERY NETWORK CACHING SYSTEM

(71) Applicant: Facebook, Inc., Menlo Park, CA (US)

(72) Inventors: Jana van Greunen, Woodside, CA (US); Huapeng Zhou, Union City, CA (US); Linpeng Tang, Princeton, NJ (US)

(21) Appl. No.: 14/970,027

(22) Filed: Dec. 15, 2015

(51) Int. Cl. G06F 12/12; G11C 7/10

(52) U.S. Cl. CPC G06F 12/122; G11C 7/1072; G06F 2212/69; G06F 2212/221

(57) ABSTRACT

Several embodiments include a method of operating a cache appliance comprising a primary memory and a secondary memory. The primary memory can implement an item-wise cache and the secondary memory can implement a block cache. The cache appliance can record an access history of a data item in the item-wise cache. The cache appliance can determine, by evaluating the access history of the data item, whether to store the data item in the block cache.

### BACKGROUND

A content delivery network (CDN) is a caching system comprising one or more cache appliances (e.g., computer servers or other computing machines) that are accessible to serve data to clients in a wide area network (WAN), for example, the Internet. A cache appliance can serve data temporarily stored therein on behalf of a data center or an application service system. Multiple cache appliances can be distributed in edge point of presences (PoPs). Popular content, e.g., a video or photo that is requested by many users, is cached as close to the users as possible. When a user requests content that is already cached, such access can be referred to as a “cache hit.” It is important to have a high cache hit rate (e.g., per item and per byte), because it lowers the latency of delivering the content to the user, and also saves the bandwidth to fetch the requested content all the way from a source data center.

In some cases, a cache appliance has both a primary data storage and a secondary data storage. For example, a cache appliance can have a random access memory (RAM) and a flash drive. The flash drive may have a much higher capacity than the RAM. In some cases, flash drives have inherent limitations to operate on a block basis. For example, a typical driver of a flash drive may expose 256 MB blocks to a processor of the cache appliance. A block in the flash drive, once written, would then need to be entirely erased before any byte in the block can be changed. The flash drive itself is not aware of data items/objects (e.g., an image file) it stores. Each block has a limited number of erase cycles before it wears out physically. A large number of writes/erase operations would slow down the latency to read items from the cache appliance.

### BRIEF DESCRIPTION OF THE DRAWINGS

FIG. 1 is a block diagram illustrating a network environment in which a caching system, in accordance with various embodiments, can be implemented.

FIG. 2 is an example of a control flow diagram illustrating a method of servicing a content request at a caching system, in accordance with various embodiments.

FIG. 3 is a block diagram illustrating a cache appliance, in accordance with various embodiments.

FIG. 4 is a block diagram illustrating functional and logical components of a cache appliance, in accordance with various embodiments.

FIG. 5 is a flow chart illustrating a method of operating a multi-tier cache appliance to process a cache lookup request using an item-wise cache as a staging area, in accordance with various embodiments.

FIG. 6 is a flow chart illustrating a method of operating a multi-tier cache appliance to compute cache priority of a data item in an item-wise cache, in accordance with various embodiments.

FIG. 7 is a flow chart illustrating a method of replacing blocks from a block cache in a cache appliance, in accordance with various embodiments.

FIG. 8 is a data flow diagram illustrating maintenance of a block cache in a cache appliance, in accordance with various embodiments.

The figures depict various embodiments of this disclosure for purposes of illustration only. One skilled in the art will readily recognize from the following discussion that alternative embodiments of the structures and methods illustrated herein may be employed without departing from the principles of embodiments described herein.

### DETAILED DESCRIPTION

Embodiments are described to include a caching system, e.g., in a CDN. For example, the caching system can include a cache appliance having a primary memory (e.g., RAM or other system memory) and a secondary memory (e.g., a flash drive, other solid-state drive, other block level storage drive, etc.). At least a portion of the primary memory can be used to implement an item-wise cache (e.g., an item-wise least recently used (LRU) cache). This portion of the primary memory can be shared by processes in the cache appliance. The secondary memory can implement a block cache. In several embodiments, the memory capacity of the block cache is significantly larger than the memory capacity of the item-wise cache in the primary memory.

In several embodiments, the caching system utilizes the item-wise cache as a staging area of the block cache. For example, when the item-wise cache is full or substantially full, the caching system can select one or more data items within the item-wise cache as one or more item eviction candidates upon eviction from the item-wise cache. The caching system can evaluate an item eviction candidate for potential inclusion into the block cache. The caching system can utilize an access pattern (e.g., frequency of items being accessed) of data items in the item-wise cache to determine what to write into the block cache.

A block cache stores data in units of constant-sized blocks and exposes access to the blocks without a filesystem. It can be advantageous for the block cache to emulate item-wise caching. For example, cache lookup requests to the caching system are based on data item requests, and hence item-wise caching or at least emulated item-wise caching would be more in-line with cache lookup activities. When the caching algorithm of a caching system is more in-line with patterns of cache lookup activities, cache hit rate of the caching system would thus increase.

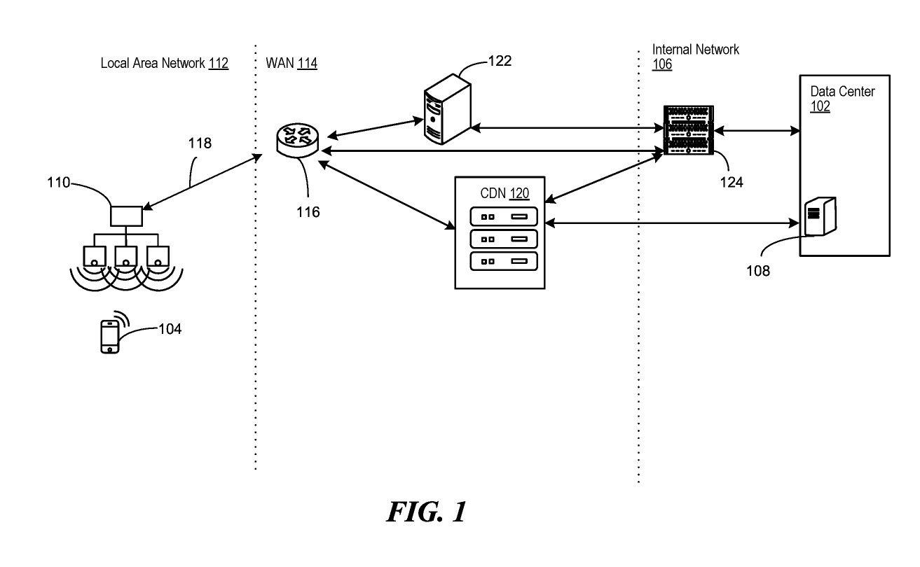

Turning now to the figures, FIG. 1 is a block diagram illustrating a network environment 100 in which a caching system, in accordance with various embodiments, can be implemented. The network environment 100 can include one or more network appliances, equipment and servers for delivering content from a data center 102 to, for example, an end-user device. The data center 102 can include one or more computing devices providing data content for a content provider system (e.g., a social networking system, an application service system, a social media system, or any combination thereof). The data center 102 can be part of an internal network 106 of the content provider system. The data center 102 can include an origination server 108. The origination server 108 can store data content made accessible through an application service.

The end-user device 104 can be connected to a local hotspot 110. The local hotspot 110 can host a local area network (LAN) 112. The local hotspot 110 can also provide access to a wide area network (WAN) 114 (e.g., via an Internet service provider (ISP) router 116). The local hotspot 112 can be connected to the ISP router 116 via a backhaul link 118. The WAN 114 can be an external network from the content provider system. The WAN 114 can be the Internet.

A content request can be generated at the end-user device 104. When the content request from the end-user device 104 arrives at the ISP router 116, the ISP router 116 can check with a content delivery network (CDN) 120 to determine whether the CDN 120 has cached a copy of the requested data item. The CDN 120 can implement a caching system, according to various embodiments, to store at least a portion of the data content of the data center 102. For example, the caching system can select what data items to store based on the popularity of data items requested.

When the CDN 120 has a copy of the requested data item, then the CDN 120 can fulfill the content request by delivering the requested content object to the end-user device 104 without passing the content request to the data center 102. When the CDN 120 does not have a copy, then the content request is propagated along the WAN 114 to the internal network 106 of the content provider system to fetch the requested content object from, for example, the origination server 108. The CDN 120 can then cache the requested content object once it is returned from the origination server 108. In some embodiments, other caching network appliances (e.g., a caching network appliance 122) can be coupled to the ISP router 116. In these embodiments, the caching network appliance 122 can serve the same functionalities as the CDN 120 to fulfill the content request.

An edge point of presence (PoP) 124 can be part of the internal network 106 of the content provider system. The edge PoP 124 can act as a proxy for the data center 102 to serve data content to end-user devices (e.g., the end-user device 104) connected to the WAN 114. In some embodiments, an edge PoP is setup closer to groups of users, for example, based on geographical locations (e.g., countries). For example, the edge PoP 124 can serve data content to the caching network appliance 122 and/or the ISP router 116, and thus indirectly to the end-user device 104. In some embodiments, the caching system, according to various embodiments, can be implemented in the edge PoP 124.

In some embodiments, when the CDN 120 that does not have a copy of the requested content object, the CDN 120 can request a copy from the edge PoP 124. In some embodiments, when the CDN 120 that does not have a copy of the requested content object, the CDN 120 can request a copy directly from the data center 102. In some embodiments, the edge PoP 124 can be pre-populated with data items from the data center 102. For example, the pre-population of data items may be based on predictive analytics and data accesses history analytics. In several embodiments, at least one of the ISP router 116, the caching network appliance 122, the CDN 120, the edge PoP 124, the origination server 108, and the local hotspot 112 can implement the caching system according to various embodiments.

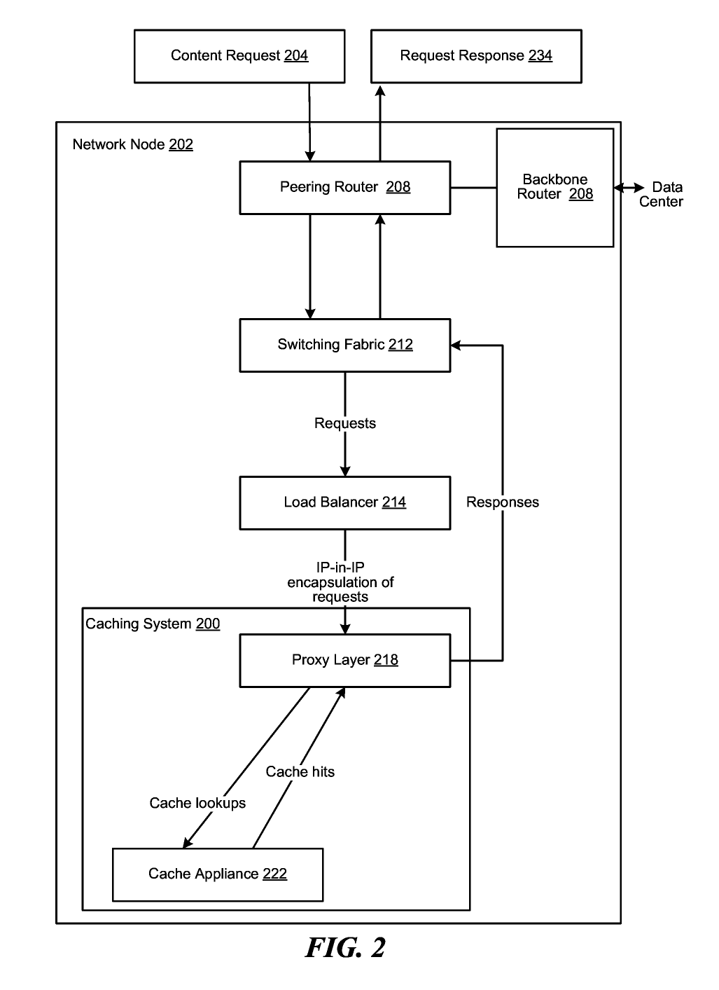

FIG. 2 is an example of a control flow diagram illustrating a method of servicing a content request at a caching system 200, in accordance with various embodiments. The caching system 200 can be configured to provide temporary data storage for data content from a content provider system.

A network node 202 (e.g., the edge PoP 124 or the CDN 120 of FIG. 1) in a WAN (e.g., the WAN 114 of FIG. 1) can receive a content request 204 via a peering router 208 from a requesting client (e.g., the end-user device 104 of FIG. 1). The peering router 208 can be coupled to a backbone router 210 and a switching fabric 212 (e.g., comprising one or more fabric switches). The backbone router 210 can be connected to an internal network (e.g., the internal network 126 of FIG. 1) of the content provider system. The switching fabric 212 can pass the content request 204 to a load balancer 214. In some embodiments, the switching fabric 212 splits ingress traffic among different load balancers. In turn, the load balancer 214 can identify the caching system 200 to fulfill the content request 204.

In some embodiments, the caching system 200 includes a proxy layer 218 that manages one or more cache appliances (e.g., a cache appliance 222). The proxy layer 218 can be implemented by one or more front-end servers or as a process implemented on the cache appliance 222. The load balancer 214 can have access to proxy layers of different caching systems. The load balancer 214 can split its traffic amongst different caching systems. The proxy layer 218 can convert the content request 204 into one or more cache lookup requests to at least one of the cache appliances.

The cache appliance 222 can implement a cache service application and a multilevel cache. For example, the multilevel cache can include a primary memory cache (e.g., implemented in a system memory module) and a secondary memory cache (e.g., implemented in one or more secondary data storage devices). In some embodiments, the primary memory cache is implemented as a least recently used (LRU) cache. In some embodiments, the secondary memory cache is implemented as an LRU cache as well.

A primary memory or a primary data storage refers to a data storage space that is directly accessible to a central processing unit (CPU) of the cache appliance 222. A secondary memory or a secondary data storage refers to a data storage space that is not under the direct control of the CPU. In one example, the primary memory is implemented in one or more RAM modules and/or other volatile memory modules and the secondary memory is implemented in one or more persistent data storage devices. In several embodiments, the primary memory cache is an item-wise cache (e.g., content of the cache can be accessed by data item/object identifiers) and the secondary memory cache is a block level cache (e.g., content of the cache can only be accessed by data block identifiers). A data block is of a pre-determined size.

In response to a cache lookup request, the cache appliance 222 can determine whether the requested data item associated with the cache lookup request is cached in its memory. The requested data item may be in the primary memory cache or the secondary memory cache. The cache service application can determine whether the requested data item is available in the caching system 200 by looking up the requested data item in the primary memory cache. If the requested data item is not found in the primary memory cache, the cache service application can look up the requested data item in an index table of data items in the secondary memory cache.

When the requested data item is available, the cache service application can send a cache hit message containing the requested data item back to the proxy layer 218. When the requested data item is unavailable, the cache service application can send a cache miss message back to the proxy layer 218. When the cache appliance 222 responds to the proxy layer 218 with a cache miss message, the proxy layer 218 can dynamically request to fetch the requested data item from a host server (e.g., the origination server 108 of FIG. 1). For example, the proxy layer 218 can contact the host server via the backbone router 210. In some embodiments, the proxy layer 218 can respond to the content request 204 directly to the switching fabric 212 (e.g., the response can bypass the load balancer 214). A response message 230 containing the requested data item can then be returned to the requesting device that issued the content request 204.

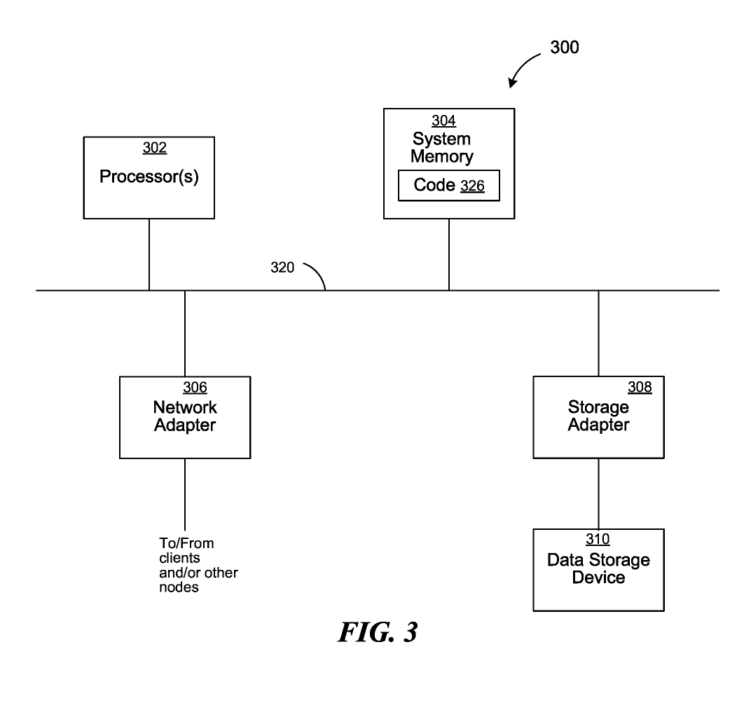

FIG. 3 is a block diagram illustrating a cache appliance 300, in accordance with various embodiments. The cache appliance 300 can include one or more processors 302, a system memory 304, a network adapter 306, a storage adapter 308, and a data storage device 310. The one or more processors 302 and the system memory 304 can be coupled to an interconnect 320. The interconnect 320 can be one or more physical buses, point-to-point connections, virtual connections, bridges, adapters, controllers, or any combination thereof.

The processors 302 are the central processing unit (CPU) of the cache appliance 300 and thus controls the overall operation of the cache appliance 300. In certain embodiments, the processors 302 accomplish this by executing software or firmware stored in the system memory 304. The processors 302 may be, or may include, one or more programmable general-purpose or special-purpose microprocessors, digital signal processors (DSPs), programmable controllers, application specific integrated circuits (ASICs), programmable logic devices (PLDs), trusted platform modules (TPMs), or the like, or any combination of such devices.

The system memory 304 is or includes the main memory of the cache appliance 300. The system memory 304 can provide run-time data storage shared by processes and applications implemented and/or executed by the one or more processors 302. The system memory 304 can include at least a random access memory (RAM) module or other volatile memory. In some embodiments, the system memory 304 can include other types of memory. In use, the system memory 304 may contain a code 326 containing instructions to execute one or more methods and/or functional/logical components described herein.

Also connected to the processors 302 through the interconnect 320 are the network adapter 306 and the storage adapter 308. The network adapter 306 provides the cache appliance 300 with the ability to communicate with remote devices, over a network and may be, for example, an Ethernet adapter or Fibre Channel adapter. The network adapter 306 may also provide the cache appliance 300 with the ability to communicate with other computers (e.g., in the same caching system/network). The storage adapter 308 enables the cache appliance 300 to access a persistent storage (e.g., the data storage device 310). The storage adapter 308 may be, for example, a Fibre Channel adapter or small computer system interface (SCSI) adapter. The storage adapter 308 can provide block level access to the data storage device 310 (e.g., flash memory, solid state memory, other persistent data storage memory, etc.). In some embodiments, the storage adapter 308 can provide only block level access to the data storage device 310.

The code 326 stored in system memory 304 may be implemented as software and/or firmware to program the processors 302 to carry out actions described above. In certain embodiments, such software or firmware may be initially provided to the cache appliance 300 by downloading it from a remote system through the cache appliance 300 (e.g., via network adapter 306).

The techniques introduced herein can be implemented by, for example, programmable circuitry (e.g., one or more microprocessors) programmed with software and/or firmware, or entirely in special-purpose hardwired circuitry, or in a combination of such forms. Special-purpose hardwired circuitry may be in the form of, for example, one or more application-specific integrated circuits (ASICs), programmable logic devices (PLDs), field-programmable gate arrays (FPGAs), etc.

Software or firmware for use in implementing the techniques introduced here may be stored on a machine-readable storage medium (e.g., non-transitory medium) and may be executed by one or more general-purpose or special-purpose programmable microprocessors. A “machine-readable storage medium”, as the term is used herein, includes any mechanism that can store information in a form accessible by a machine (a machine may be, for example, a computer, network device, cellular phone, personal digital assistant (PDA), manufacturing tool, any device with one or more processors, etc.). For example, a machine-accessible storage medium includes recordable/non-recordable media (e.g., read-only memory (ROM); random access memory (RAM); magnetic disk storage media; optical storage media; flash memory devices; etc.), etc. The term “logic”, as used herein, can include, for example, programmable circuitry programmed with specific software and/or firmware, special-purpose hardwired circuitry, or a combination thereof.

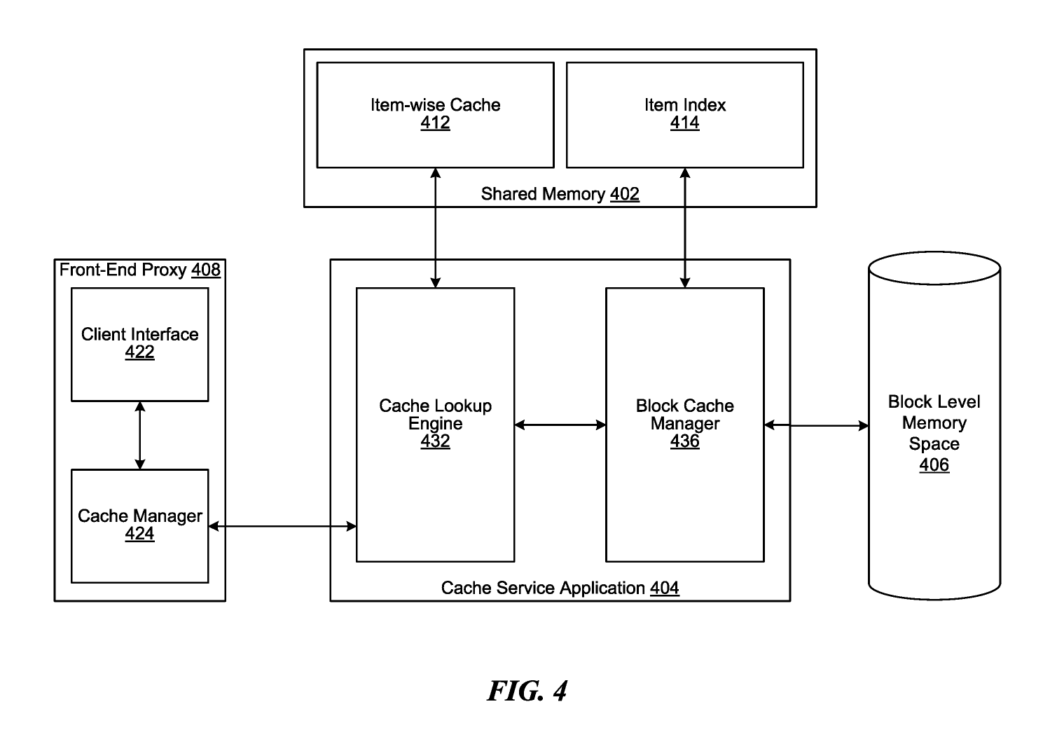

FIG. 4 is a block diagram illustrating functional and logical components of a cache appliance 400, in accordance with various embodiments. The cache appliance 400 can be part of a content delivery network that provides temporary data storage, for one or more frequently requested data items, in one or more edge point of presences in a wide area network. The cache appliance 400 can include a shared memory 402 (e.g., hosted in the system memory 304 of FIG. 3), a cache service application 404 (e.g., implemented by the one or more processors 302 of FIG. 3), and a block level memory space 406 (e.g., hosted in the data storage device 310 of FIG. 3). The cache appliance 400 can include or be coupled to a front-end proxy 408 (e.g., implemented by the one or more processors 302 of FIG. 3 or hosted by a front-end device separate from the cache appliance 400). The cache appliance 400 can be the cache appliance 300 of FIG. 3.

The cache appliance 400 can implement an item-wise cache 412 in the shared memory 402. The cache appliance 400 can also implement an item index 414 that stores one or more block pointers corresponding to one or more data items (e.g., data objects and/or data files that have variable sizes). Each of the block pointers can point to one or more blocks in the block level memory space 406. In some embodiments, size of a data item is configured to be always smaller than a block, for example, by chunking a data item into sections that is at maximum the size of a block. The item-wise cache 412 can be arranged for lookup by item identifier or by item attribute (e.g., creation date, access date, size, type).

The item index 414 can maintain a list of data items stored in the block level memory space 406. In some embodiments, the data items are encrypted when stored in the block level memory space 406. In these embodiments, the item index 414 can be configured to store one or more encryption keys to access the encrypted blocks in the block level memory space 406. For example, each block or each portion in each block in the block level memory space 406 can be encrypted via the Advanced Encryption Standard (AES). The item index 414 can store the AES keys used to decrypt the blocks or portions of the blocks.

A client interface 422 of the front-end proxy 408 can receive a content request from an external device. A request manager 424 of the front-end proxy 408 can then generate a cache lookup request based on the content request. The cache lookup request is sent to a cache lookup engine 432 of the cache service application 404. The cache lookup engine 432 can respond to cache lookup requests from the request manager 434. The cache service application 404 can respond to a cache lookup request with a cache hit message (e.g., containing the requested data item) or a cache miss message. The cache lookup engine 432 can first lookup whether the requested data item is in the item-wise cache 412. If not, the cache lookup engine 432 can look up, via a block cache management engine 436, whether the requested data item is in the block level memory space 406 by looking up the item index 414.

In some embodiments, the block cache management engine 436 is configured to update the item index 414 whenever one or more new data items are stored in the block level memory space 406. The block cache management engine 436 can also be configured to operate a storage adapter (e.g., the storage adapter 308 of FIG. 3) to access input/output (I/O) of the block level memory space 406. For example, the block cache management engine 436 can write a new block into the block level memory space 406.

When the requested data item is available, the cache lookup engine 432 can send a cache hit message containing the requested data item back to the request manager 424. When the requested data item is unavailable, the cache lookup engine 432 can send a cache miss message back to the request manager 424. When the request manager 424 receives the cache hit message, the request manager 424 can cause the client interface 422 to respond to the content request.

In some embodiments, the block cache management engine 436 can store the item index 414 only in the shared memory 402 without backup to a secondary storage drive. In some embodiments, because the cache lookup engine 432 stores the item-wise cache 412 in the shared memory 402, when the cache service application 404 restarts (e.g., due to failure or error), the restarted cache service application 404 is capable of re-using the item-wise cache 412 from prior to the restart.

Functional/logical components (e.g., applications, engines, modules, and databases) associated with the cache appliance 400 can be implemented as circuitry, firmware, software, or other functional instructions. For example, the functional/logical components can be implemented in the form of special-purpose circuitry, in the form of one or more appropriately programmed processors, a single board chip, a field programmable gate array, a network-capable computing device, a virtual machine, a cloud computing environment, or any combination thereof. For example, the functional/logical components described can be implemented as instructions on a tangible storage memory capable of being executed by a processor or other integrated circuit chip. The tangible storage memory may be volatile or non-volatile memory. In some embodiments, the volatile memory may be considered “non-transitory” in the sense that it is not a transitory signal. Memory space and storages described in the figures can be implemented with the tangible storage memory as well, including volatile or non-volatile memory.

Each of the functional/logical components may operate individually and independently of other functional/logical components. Some or all of the functional/logical components may be executed on the same host device or on separate devices. The separate devices can be coupled through one or more communication channels (e.g., wireless or wired channel) to coordinate their operations. Some or all of the functional/logical components may be combined as one component. A single functional/logical component may be divided into sub-components, each sub-component performing separate method step or method steps of the single component.

In some embodiments, at least some of the functional/logical components share access to a memory space. For example, one functional/logical component may access data accessed by or transformed by another functional/logical component. The functional/logical components may be considered “coupled” to one another if they share a physical connection or a virtual connection, directly or indirectly, allowing data accessed or modified by one functional/logical component to be accessed in another functional/logical component. In some embodiments, at least some of the functional/logical components can be upgraded or modified remotely (e.g., by reconfiguring executable instructions that implements a portion of the functional/logical components). The systems, engines, or devices described may include additional, fewer, or different functional/logical components for various applications.

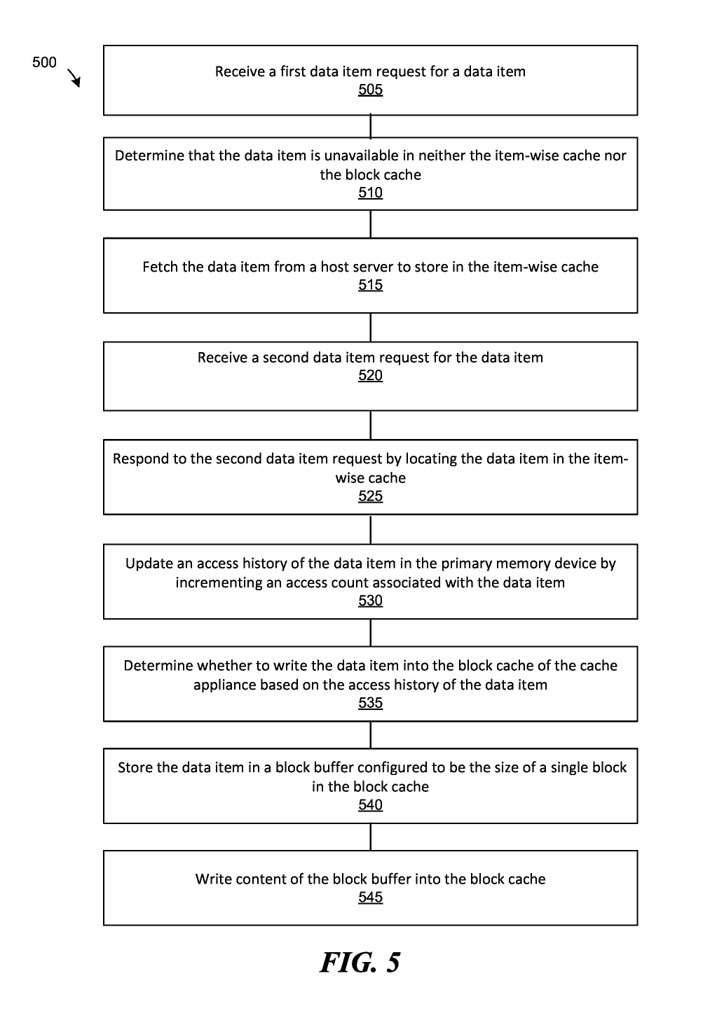

FIG. 5 is a flowchart illustrating a method 500 of operating a multi-tier cache appliance (e.g., the cache appliance 300 of FIG. 3 and/or the cache appliance 400 of FIG. 4) to process a cache lookup request using an item-wise cache as a staging area, in accordance with various embodiments. In some embodiments, the multi-tier cache appliance is considered “multi-tier” because it implements at least the item-wise cache in a primary data storage (e.g., RAM memory) and a block cache in a secondary data storage (e.g., solid-state memory). The item-wise cache can be configured as a staging area for the block cache.

At step 505, the multi-tier cache appliance can receive a first data item request for a data item. In response to the data item request, at step 510, the multi-tier cache appliance can determine that the data item is unavailable in neither the item-wise cache nor the block cache. At step 515, the multi-tier cache appliance can fetch the data item from a host server/data center to store in the item-wise cache. This step can be performed in response to step 510. Afterwards, at step 520, the multi-tier cache appliance can receive a second data item request for the data item.

At step 525, the multi-tier cache appliance can respond to the second data item request by locating the data item (e.g., fetched in step 515) in the item-wise cache. At step 530, the multi-tier cache appliance can update an access history of the data item in the primary data storage by incrementing an access count associated with the data item. In some embodiments, step 530 can occur in response to receiving the second data item request. In some embodiments, step 530 can occur in response to step 525.

At step 535, the multi-tier cache appliance can determine whether to write the data item into the block cache of the multi-tier cache appliance based on the access history of the data item. Determining whether to write the data item into the block cache can occur after, when, or in response to the RAM being beyond a threshold percentage (e.g., 80% or 90%) of being full. At step 540, the multi-tier cache appliance can store the data item a block buffer configured to be the size of a single block in the block cache. In several embodiments, blocks in the block cache all have the same size. Storing the data item in the block buffer can be in response to determining to write the data item in the block cache (e.g., step 535).

At step 545, the multi-tier cache appliance can write content of the block buffer into the block cache. For example, the multi-tier cache appliance can write the content of the block buffer into the block cache when the block buffer is full or substantially full. In some embodiments, the multi-tier cache appliance can maintain multiple block buffers in the primary data storage. When the block buffers are full or substantially full (e.g., according to a threshold percentage), the multi-tier cache appliance can sequentially write the content of the block buffers into the block cache.

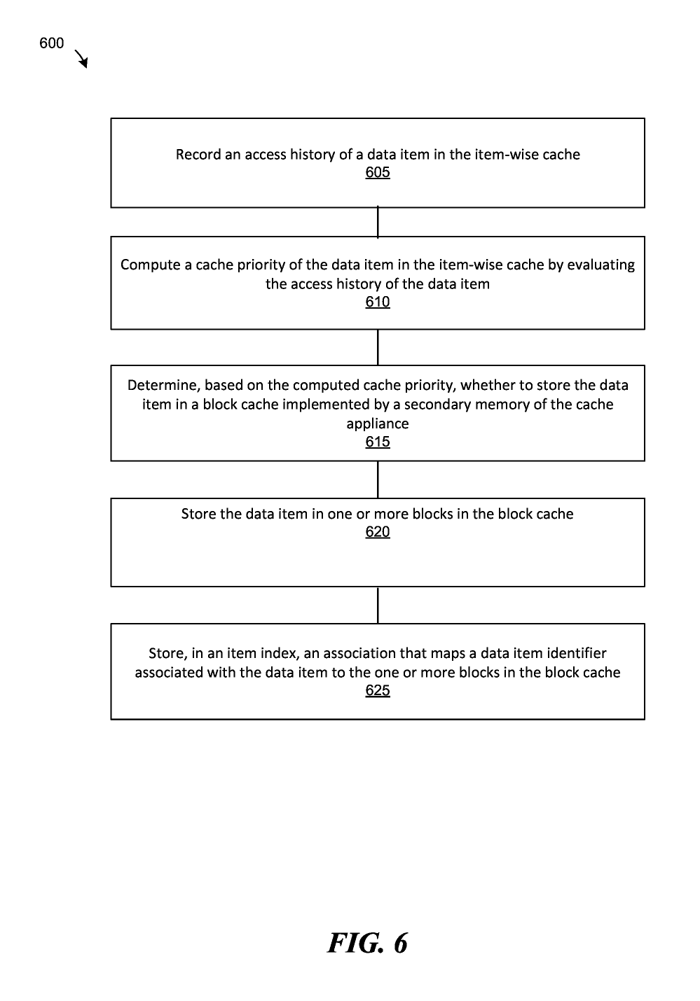

FIG. 6 is a flowchart illustrating a method 600 of operating a multi-tier cache appliance (e.g., the cache appliance 300 of FIG. 3 and/or the cache appliance 400 of FIG. 4) to compute cache priority of a data item, in accordance with various embodiments. The multi-tier cache appliance can implement an item-wise cache (e.g., the item-wise cache 412 of FIG. 4) in a primary data storage (e.g., RAM memory) and a block cache (e.g., the block level memory space 406 of FIG. 4) in a secondary data storage (e.g., solid-state memory). The item-wise cache can be configured as a staging area for the block cache. The item-wise cache can be configured as a least recently used (LRU) cache.

At step 605, the multi-tier cache appliance can record an access history of a data item in the item-wise cache. The data item can be amongst multiple data items in the item-wise cache. For example, the multi-tier cache appliance can record access histories of all data items in the item wise cache. At step 610, the multi-tier cache appliance can compute a cache priority of the data item in the item-wise cache by evaluating the access history of the data item. In some embodiments, the multi-tier cache appliance can schedule a minimum evaluation period for the data item to be in the item-wise cache. In some embodiments, the multi-tier cache appliance can compute the cache priority after the minimum evaluation period enables the access history to collect, if any, a certain amount of accumulated data.

For example, the multi-tier cache appliance can compute the cache priority of the data item based on an access count, an access frequency within a time window, a requestor diversity measure, size of the data item, item type of the data item, or any combination thereof. In some embodiments, computing the cache priority includes computing the cache priority of the data item by evaluating the access history of the data item against at least an access history of another data item.

At step 615, the multi-tier cache appliance can determine, based on the computed cache priority, whether to store the data item in the block cache implemented by the secondary data storage. For example, the multi-tier cache appliance can determine to store the data item when the computed cache priority is beyond a predetermined threshold. In some embodiments, the multi-tier cache appliance determines whether to store the data item occurs when the item-wise cache is full or substantially full. In some embodiments, the multi-tier cache appliance determines whether to store the data item when the data item is about to be evicted from the item-wise cache (e.g., when the data item is a least recently requested data item in the item-wise cache).

At step 620, the multi-tier cache appliance can store the data item in one or more blocks in the block cache. For example, the multitier cache appliance can store the data item in response to determining that the data item is to be stored in the block cache. At step 625, the multi-tier cache appliance can store, in an item index, an association that maps a data item identifier associated with the data item to the one or more blocks in the block cache.

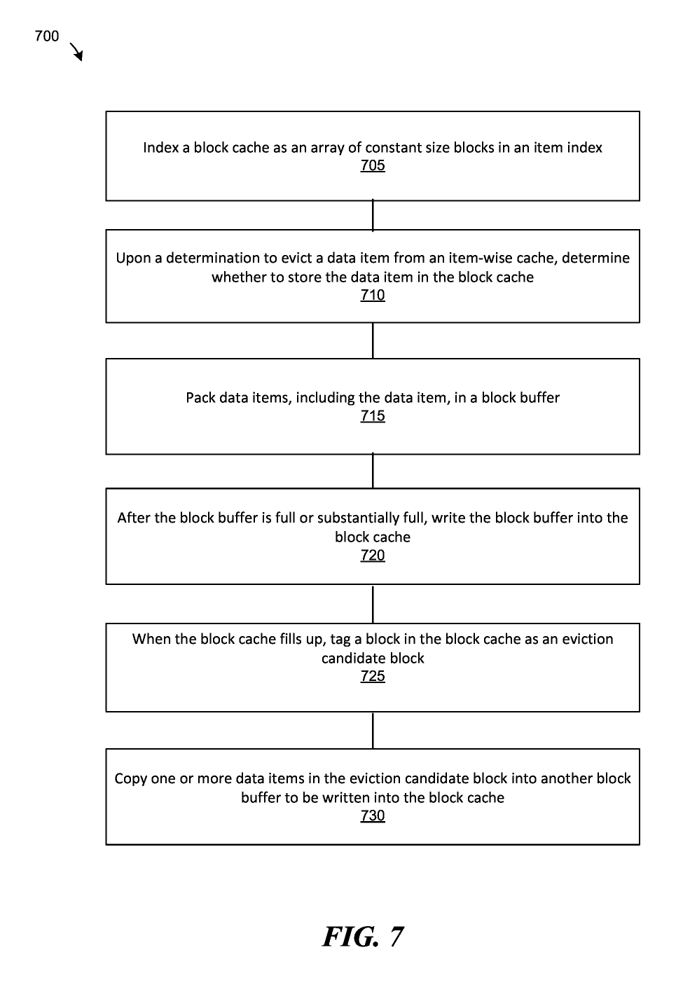

FIG. 7 is a flowchart illustrating a method 700 of replacing blocks from a block cache (e.g., the block level memory space 406 of FIG. 4) in a cache appliance (e.g., the cache appliance 300 of FIG. 3 and/or the cache appliance 400 of FIG. 4), in accordance with various embodiments. The cache appliance can maintain the block cache in a secondary data storage (e.g., a solid-state drive). The cache appliance can also maintain an item-wise cache in a primary data storage (e.g., RAM memory). The item-wise cache can be configured as a staging area for the block cache. The item-wise cache can be configured as a least recently used (LRU) cache.

At step 705, the cache appliance can index the block cache as an array of constant-sized blocks. For example, the cache appliance can generate an item index that references the block cache according to its position in the array of constant-sized blocks. At step 710, the cache appliance can determine whether to store a data item in the block cache. For example, this determination can be made when the data item is about to be evicted from the item-wise cache. In the example of the LRU cache, the data item can become a candidate for eviction from the item-wise cache when the data item is the least recently used data item in the item-wise cache.

At step 715, the cache appliance can pack data items, including the data item from step 710, in a block buffer that is the same size as a single block in the block cache. The block buffer can be stored in the primary data storage. At step 720, after or in response to the block buffer being full or substantially full, the cache appliance can write the block buffer into the block cache. At step 725, when the block cache fills up, the cache appliance can tag a block (e.g., the least recently used block) in the block cache as an eviction candidate block. At step 730, the cache appliance can copy one or more data items in the eviction candidate block into another block buffer in the primary data storage to save the data items from eviction. The cache appliance can implement various methods to determine which data items in the eviction candidate block are most valuable, and thus deserve to be copied over and saved from eviction. Later when this other block buffer is full or substantially full, the cache appliance can write the other block buffer into a block in the block cache.

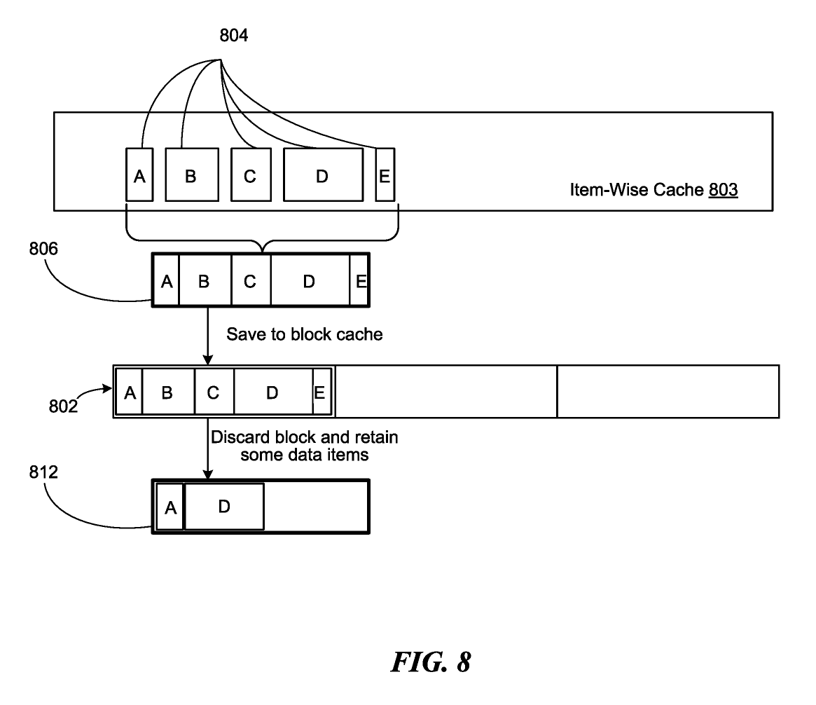

FIG. 8 is a data flow diagram illustrating maintenance of a block cache 802 in a cache appliance (e.g., the cache appliance 300 of FIG. 3 and/or the cache appliance 400 of FIG. 4), in accordance with various embodiments. The cache appliance can utilize an item-wise cache 803 as a staging area for the block cache 802. For example, the item-wise cache 803 can store data items 804 of various sizes. Upon eviction of a data item from the item-wise cache 803, the cache appliance can determine whether to add the data item into a block buffer 806. In the illustrated example, the cache appliance chooses to add (e.g., sequentially) the data items 804 to the block buffer 806. After the block buffer 806 is full or substantially full, the cache appliance can add the block buffer 806 into a block 810 in the block cache 802.

In some embodiments, as a mechanism to prevent unnecessary eviction, when the cache appliance evicts a block from the block cache 802, at least a subset of data items in the block cache 802 are saved back to a block buffer 812 (e.g., the block buffer 806 or another block buffer).

In some cases, a large number of data items are written to each block of the block cache 802. When a block is “evicted,” not all of the data items in the block are evicted. For example, some data items in the block can be copied over to other blocks as they still need to be kept in the block cache 802. If a large portion of the block needs to be copied, then it can lead to a large number of wasted erases and writes. Accordingly, in several embodiments, the cache appliance implements caching strategies to evict blocks with the least number of data items that need to be copied over.

The cache appliance can avoid storing data that change rapidly in the block cache 802 to avoid frequent writes (e.g., that may reduce the lifetime of the secondary data storage). Therefore, the cache appliance can store the body/content of a data item in the block cache, and keep an item index (e.g., in the primary data storage) along with information about when the data item is last accessed or how often is has been accessed. These metrics are used to determine whether the data item should be evicted from the block cache 802 or not. In some embodiments, caching algorithms keeps an ordered queue or list of these data items so that the worst items can be easily found and evicted from the block cache 802 when a new items needs to be cached.

While processes or blocks are presented in a given order in flow charts of this disclosure, alternative embodiments may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. In addition, while processes or blocks are at times shown as being performed in series, these processes or blocks may instead be performed in parallel, or may be performed at different times. When a process or step is “based on” a value or a computation, the process or step should be interpreted as based at least on that value or that computation.

Some embodiments of the disclosure have other aspects, elements, features, and steps in addition to or in place of what is described above. These potential additions and replacements are described throughout the rest of the specification.

What is claimed is:

1. A computer-implemented method, comprising:
recording an access history of a data item in a least recently used (LRU) cache implemented in a primary memory of a cache appliance;
computing a cache priority of the data item in the LRU cache by evaluating the access history of the data item;
determining, based on the computed cache priority, whether to store the data item in a block cache implemented by a secondary memory of the cache appliance;
storing the data item in one or more blocks in the block cache; and
storing, in an item index, an association that maps a data item identifier associated with the data item to the one or more blocks in the block cache.

2. The computer-implemented method of claim 1, wherein computing the cache priority of the data item based on an access count, an access frequency within a time window, a requestor diversity measure, size of the data item, item type of the data item, or any combination thereof.

3. The computer-implemented method of claim 1, wherein the data item is amongst one or more other data items in the LRU cache; and wherein computing the cache priority includes computing the cache priority of the data item by evaluating the access history of the data item against at least an access history of another data item.

4. The computer-implemented method of claim 1, further comprising scheduling a minimum evaluation period for the data item to be in the LRU cache prior to storing the data item in the block cache.

5. The computer-implemented method of claim 1, wherein said determining whether to store the data item occurs when the LRU cache is full or substantially full.

6. The computer-implemented method of claim 1, wherein said determining whether to store the data item occurs when the data item is a least recently requested data item in the LRU cache.

7. A cache appliance, comprising:
a random access memory (RAM) configured to implement an item-wise cache;
a secondary storage drive configured to implement a block cache;
wherein the item-wise cache is configured to serve as a staging area for one or more data items to be stored in the block cache and to maintain an item index to identify one or more blocks of the block cache that store the data items;
a processor configured to:
update an access history of the data item in RAM, responsive to one or more repeated requests to access the data item while the data item is in the item-wise cache; and
determine whether to write the data item into the block cache based on the access history of the data item.

8. The cache appliance of claim 7, wherein the processor is configured to fetch the data item from an external host server when the data item is requested prior to either the item-wise cache or the block cache having stored the data item.

9. The cache appliance of claim 7, wherein the processor is configured to receive a data item request for the data item and, responsive to the data item request, to increment an access count associated with the data item, wherein the access history includes the access count.

10. The cache appliance of claim 7, wherein the item-wise cache is implemented as a least recently used (LRU) cache.

11. The cache appliance of claim 7, wherein the secondary storage drive is a solid state drive.

12. The cache appliance of claim 7, wherein the processor is configured to store the item index only in the RAM without backup to the secondary storage drive.

13. The cache appliance of claim 7, wherein the processor is configured to store the item-wise cache is a shared memory space of the RAM, wherein when a cache service application restarts, the restarted cache service application is capable of re-using the item-wise cache.

14. A computer readable data storage memory storing computer-executable instructions that, when executed, cause a computer system to perform a computer-implemented method, the instructions comprising:
instructions for receiving a data item request for a data item at a cache appliance, wherein the cache appliance implements an item-wise cache in a random access memory (RAM) and a block cache in a secondary memory, wherein the item-wise cache is configured as a staging area for the block cache;
instructions for responding to the data item request by locating the data item in the item-wise cache;
instructions for responsive to the data item request, updating an access history of the data item in the RAM by incrementing an access count associated with the data item; and
instructions for determining whether to write the data item into the block cache of the cache appliance based on the access history of the data item.

15. The computer readable data storage memory of claim 14, wherein the cache appliance is part of a content delivery network that provides temporary data storage, for one or more frequently requested data items, in one or more edge point of presences in a wide area network.

16. The computer readable data storage memory of claim 14, wherein the instructions further comprises instructions for fetching the data item from a host server to store in the item-wise cache prior to receiving the data item request.

17. The computer readable data storage memory of claim 16, wherein said fetching is responsive to receiving a previous data item request for the data item when the data item yet is not stored in either the item-wise cache or the block cache.

18. The computer readable data storage memory of claim 14, wherein said determining whether to write the data item occurs when the RAM is beyond a threshold percentage of being full.

19. The computer readable data storage memory of claim 14, wherein the instructions further comprises:
instructions for, responsive to determining to write the data item into the block cache, storing the data item in a block buffer configured to be size of a single block in the block cache; and
instructions for, when the block buffer is full or substantially full, writing content of the block buffer into the block cache.

20. The computer-implemented method of claim 19, wherein the instructions further comprises:
instructions for maintaining multiple block buffers; and
instructions for, when the block buffers are full or substantially full, sequentially writing content of the block buffers into the block cache.
